(19) United States
(12) Patent Application Publication
(10) Pub. No.: US 2023/0179152 A1
(43) Pub. Date: Jun. 8, 2023

(54) LOW NOISE AMPLIFIER AND OPERATING METHOD THEREOF

(71) Applicant: SAMSUNG ELECTRO-MECHANICS CO., LTD., Suwon-si (KR)

(72) Inventors: Nackgyun SEONG, Suwon-si (KR); Hyungoo JEON, Suwon-si (KR)

(73) Assignee: SAMSUNG ELECTRO-MECHANICS CO., LTD., Suwon-si (KR)

(21) Appl. No.: 17/863,729

(22) Filed: Jul. 13, 2022

(30) Foreign Application Priority Data
Dec. 3, 2021 (KR) 10-2021-0171990

(51) Int. Cl. H03F 1/56; H03F 3/193

(52) U.S. Cl. CPC H03F 1/565; H03F 3/193; H03F 2200/451; H03F 2200/294; H03F 2200/72; H03F 2200/75; H03F 2200/387; H03F 2200/222; H03F 2200/225; H03F 2200/391

(57) ABSTRACT

A low-noise amplifier is provided. The low-noise amplifier includes a first transistor configured to amplify an input signal; a second transistor which forms a cascade structure with the first transistor and configured to amplify an output signal of the first transistor; and a third transistor which forms a cascode structure together with the first transistor and configured to amplify the output signal of the first transistor, wherein a first signal including a sum of the output signal of the second transistor and the output signal of the third transistor is output to an output terminal.

### CROSS-REFERENCE TO RELATED APPLICATIONS

This application claims the benefit under 35 USC § 119(a) of Korean Patent Application No. 10-2021-0171990 filed on Dec. 3, 2021, in the Korean Intellectual Property Office, the entire disclosure of which is incorporated herein by reference for all purposes.

### BACKGROUND

### 1. Field

The following description relates to a low-noise amplifier and an operating method thereof.

### 2. Description of Related Art

A low-noise amplifier (LNA) may be included in a receiving terminal of a wireless communication device, and may amplifies a weak signal received through an antenna into a signal that is strong against noise. This low-noise amplifier is an important circuit that determines the noise performance of the receiving terminal. Additionally, the low-noise amplifier should satisfy high voltage gain and low current consumption characteristics, and accordingly, the development of low-power low-noise amplifiers that implement the current reuse structure is beneficial.

However, the low-noise amplifier which has the current reuse structure may have a relatively low value of a third order intercept point (IP3) characteristic compared to other structures due to a high voltage gain.

The above information disclosed in this Background section is only for enhancement of understanding of the background of the invention, and therefore it may contain information that does not form the prior art that is already known in this country to a person of ordinary skill in the art.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, a low-noise amplifier includes a first transistor configured to amplify an input signal; a second transistor configured to amplify an output signal of the first transistor; and a third transistor configured to amplify the output signal of the first transistor, wherein a first signal comprising a sum of an output signal of the second transistor and an output signal of the third transistor is output to an output terminal.

The second transistor may form a cascade structure with the first transistor.

The third transistor forms a cascode structure with the first transistor.

A drain of the second transistor and a drain of the third transistor may be connected to each other at a node, and the first signal may be output from the node.

The second transistor may be configured to have a common-source structure, and the third transistor is configured to have a common-gate structure.

The first transistor may be configured to have a common-source structure.

The output signal of the first transistor may be input to a control terminal of the second transistor, and the output signal of the first transistor may be input to a source of the third transistor.

The low-noise amplifier may further include an input matching network connected to an input terminal to which an input signal is input, and a control terminal of the first transistor, and the input matching network may include an inductor which has a first terminal connected to the input terminal; a first capacitor connected between a second terminal of the inductor and the control terminal of the first transistor; and a second capacitor connected between the control terminal of the first transistor and a source of the first transistor.

The low-noise amplifier may include an RF (Radio Frequency) choke circuit connected between a drain of the first transistor from which the output signal of the first transistor is output, and a source of the second transistor.

The RF choke circuit may include an inductor connected between the drain of the first transistor and the source of the second transistor; and a capacitor connected between the source of the second transistor and a ground.

A phase for a nonlinear component included in the output signal of the second transistor and a phase for a nonlinear component included in the output signal of the third transistor may be opposite to each other.

In a general aspect, a method includes amplifying a received Radio Frequency (RF) signal by a first transistor and generating a first amplified signal; amplifying the first amplified signal with a second transistor to generate a second amplified signal; amplifying the first amplified signal with a third transistor to generate a third amplified signal; and combining the second amplified signal and the third amplified signal, and outputting the combined signal to an output terminal.

The second transistor may be connected to the first transistor with a cascade structure.

The third transistor may be connected to the first transistor with a cascode structure.

The second amplified signal and the third amplified signal may be combined at a node where a drain of the second transistor and a drain of the third transistor are connected.

A phase for a nonlinear component included in the second amplified signal and a phase for a nonlinear component included in the third amplified signal may be opposite to each other.

The generating of the second amplified signal may include inputting the first amplified signal to a control terminal of the second transistor; and amplifying the first amplified signal to generate the second amplified signal, and outputting the generated second amplified signal to the drain of the second transistor.

The generating of the third amplified signal may include inputting the first amplified signal to a source of the third transistor; and amplifying the first amplified signal to generate the third amplified signal, and outputting the generated third amplified signal to the drain of the third transistor.

Other features and aspects will be apparent from the following detailed description, the drawings, and the claims.

### BRIEF DESCRIPTION OF DRAWINGS

FIG. 1 illustrates a circuit diagram of an example low-noise amplifier, in accordance with one or more embodiments.

FIG. 2 illustrates a view of a phase relation of an RF signal in a low-noise amplifier of FIG. 1.

FIG. 3 illustrates a circuit of a detailed configuration of a low-noise amplifier of FIG. 1.

FIG. 4 illustrates a graph of a simulation result of an example low-noise amplifier, in accordance with one or more embodiments.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness, noting that omissions of features and their descriptions are also not intended to be admissions of their general knowledge.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Throughout the specification, when an element, such as a layer, region, or substrate is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

The terminology used herein is for the purpose of describing particular examples only, and is not to be used to limit the disclosure. As used herein, the singular forms “a,” “an,” and “the” are intended to include the plural forms as well, unless the context clearly indicates otherwise. As used herein, the term “and/or” includes any one and any combination of any two or more of the associated listed items. As used herein, the terms “include,” “comprise,” and “have” specify the presence of stated features, numbers, operations, elements, components, and/or combinations thereof, but do not preclude the presence or addition of one or more other features, numbers, operations, elements, components, and/or combinations thereof.

In addition, terms such as first, second, A, B, (a), (b), and the like may be used herein to describe components. Each of these terminologies is not used to define an essence, order, or sequence of a corresponding component but used merely to distinguish the corresponding component from other component(s).

Unless otherwise defined, all terms, including technical and scientific terms, used herein have the same meaning as commonly understood by one of ordinary skill in the art to which this disclosure pertains and after an understanding of the disclosure of this application. Terms, such as those defined in commonly used dictionaries, are to be interpreted as having a meaning that is consistent with their meaning in the context of the relevant art and the disclosure of this application, and are not to be interpreted in an idealized or overly formal sense unless expressly so defined herein.

Also, in the description of example embodiments, detailed description of structures or functions that are thereby known after an understanding of the disclosure of the present application will be omitted when it is deemed that such description will cause ambiguous interpretation of the example embodiments.

Throughout this specification, the RF signal may have a format of, but not limited to, Wi-Fi (IEEE 802.11 family, etc.), WiMAX (IEEE 802.16 family, etc.), IEEE 802.20, long term evolution (LTE), Evolution-Data Optimized (Ev-DO), high-speed packet access (HSPA), high-speed downlink packet access (HSDPA), high-speed uplink packet access (HSUPA), Enhanced Data GSM Evolution (EDGE), Global System for Mobile communication (GSM), Global Positioning System (GPS), General Packet Radio Service (GPRS), Code Division Multiple Access (CDMA), Time Division Multiple Access (TDMA), digital enhanced cordless communication (DECT), Bluetooth, third generation (3G), fourth generation (4G), fifth generation (5G), and any other arbitrary wireless and wired protocols designated later, but is not limited thereto.

Additionally, unless explicitly described to the contrary, the word “comprise”, and variations such as “comprises” or “comprising”, will be understood to imply the inclusion of stated elements but not the exclusion of any other elements.

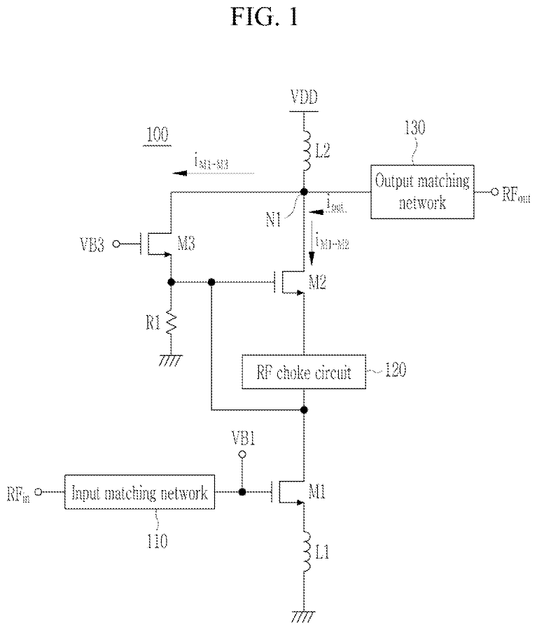

FIG. 1 illustrates a circuit diagram of an example low-noise amplifier 100, in accordance with one or more embodiments.

As illustrated in FIG. 1, a low-noise amplifier 100, in accordance with one or more embodiments, may include an input matching network 110, a transistor M1, a transistor M2, a transistor M3, an RF choke circuit 120, and an output matching network 130. Additionally, the low-noise amplifier 100 may further include a first inductor L1, a second inductor L2, and a resistor R1.

Referring to FIG. 1, the transistors M1, M2, and M3 may be implemented with various transistors such as electric field effect transistors (FET) and bipolar transistors. Additionally, in FIG. 1, each transistor M1, M2, and M3 is indicated as an N-type. However, this is only an example, and the transistors may be replaced with a P-type. Hereinafter, it is assumed that the transistors M1, M2, and M3 are the FETs for better understanding and ease of description, but may be replaced with other transistors.

The input matching network 110 may be connected between an RF input terminal, RFin, and a control terminal (e.g., a gate) of the transistor M1, and may perform impedance matching between an input RF (Radio Frequency) signal and the transistor M1. In a non-limiting example, the input matching network 110 may be implemented with a combination of at least one of an inductor and a capacitor, but is not limited thereto.

The transistor M1 may be an amplifying transistor, and the RF signal to be amplified may be input to the gate of the transistor M1. A bias voltage VB1 may be applied to the gate of the transistor M1. Based on the bias voltage VB1, the transistor M1 may perform an amplification operation. The amplified signal may then be output to the drain of the transistor M1. Since the RF signal to be amplified is input to the gate of the transistor M1 and the amplified signal is output to the drain of the transistor M1, the transistor M1 may have a common-source structure.

The inductor L1 may be connected between the source of the transistor M1 and ground. The inductor L1 may be a degeneration circuit that may improve the impedance matching of the input matching network 110. Accordingly, the inductor L1 may optimize the gain and a noise figure of the low-noise amplifier 100. When the transistor M1 is implemented as a bipolar transistor, the inductor L1 may provide emitter degeneration. Additionally, when the transistor M1 is implemented as an electric field effect transistor (FET), the inductor L1 may provide source degeneration. The inductor L1 may be replaced with a resistor to perform the role of a degeneration circuit.

The transistor M2 may form a cascade structure together with the transistor M1, and may amplify an output signal of the transistor M1. The gate of transistor M2 may be connected to the drain of transistor M1, and the RF signal to be amplified may be input to the gate of the transistor M2. That is, the gate of the transistor M2 may receive and amplify the RF signal output from the drain of the transistor M1, and the drain of the transistor M2 may output the amplified signal. Accordingly, the transistor M2 may have a common-source structure.

In an example, the RF choke circuit 120 may be connected between the source of the transistor M2 and the drain of the transistor M1. The RF choke circuit 120 may prevent the output RF signal of the transistor M1 (the RF signal output from the drain of the transistor M1) from flowing into the source of the transistor M2. In an example, the RF choke circuit 120 may be implemented through an inductor.

The transistor M3 may form a cascode structure together with the transistor M1 and may amplify the output signal of the transistor M1. The source of the transistor M3 may be connected to the drain of the transistor M1, and the RF signal to be amplified is input to the source of the transistor M3. That is, the source of the transistor M3 may receive and amplify the RF signal output from the drain of the transistor M1, and the drain of the transistor M3 may output the amplified signal. Additionally, a bias voltage VB3 may be applied to the gate of the transistor M3. On the basis of the bias voltage VB3, the transistor M3 may perform an amplification operation. Accordingly, the transistor M3 may have a common-gate structure.

The drain of transistor M2 and the drain of transistor M3 may be connected to each other, and as illustrated in FIG. 1, a node where the transistor M2 and the transistor M3 are connected to each other is represented by N1. That is, the output signal of the transistor M2 and the output signal of the transistor M3 are summed, and two combined output signals correspond to the final output signal RFₒᵤₜ of the low-noise amplifier 100. Since the output signal of the transistor M2 and the output signal of the transistor M3 are summed, the nonlinear characteristic of the low-noise amplifier 100 may be improved, which is described in more detail below.

In an example, the inductor L2 may be connected between a power supply voltage VDD and the node N1. The transistor M2 and the transistor M3 may receive the power supply voltage VDD through the inductor L2. In an example, the inductor L2 may perform an RF choke function or may perform an output impedance matching function.

The output matching network 130 may be connected between the node N1 and the RF output terminal RFout, and may perform output impedance matching. The output matching network 130 may be implemented by a combination of at least one of an inductor and a capacitor, but is not limited thereto. In a non-limited example, the inductor L2 may be included in the output matching network 130.

Referring to FIG. 1, in view of the RF signal, the transistor M1 and the transistor M2 may form a cascade connection structure between each other, so that a high voltage gain may be obtained. In view of the DC (Direct Current) signal, the transistor M1 and the transistor M2 may form a cascade structure with each other, through which the supply current supplied from the power supply voltage VDD may be shared. That is, the transistor M1 and the transistor M2 may form a current reuse structure, and accordingly, current consumption may be reduced. On the other hand, from the viewpoint of the RF signal, the transistor M1 and the transistor M3 may form a cascode structure between each other, through which the non-linear characteristic may be improved. Hereinafter, the reason why the nonlinear characteristic of the low-noise amplifier 100 according to an example is improved is described in detail.

Typically, in the amplifier, the nonlinear characteristic is determined by nonlinear transconductance (g″m), and the nonlinear transconductance (g″m) satisfies Equation 1 below. In an example, the nonlinear transconductance (g″m) represents a third order transconductance.

$$IM 3 = \frac{3}{4} \frac{{g}_{m}^{″}}{{g}_{m}} {IP}_{3}^{2} = 1 , {IP}_{3} = \sqrt{\frac{4}{3} \vert \frac{{g}_{m}}{{g}_{m}^{″}} \vert} \qquad Equation 1$$

Referring to Equation 1, IM3 represents the third order intermodulation, and gm represents the linear transconductance of the amplifier. Referring to Equation 1, as the nonlinear transconductance (g″ₘ) is minimized, it may be seen that the nonlinear characteristic is improved.

In an example, Equation 2 below represents an output current of a general N-type metal oxide semiconductor FET (NMOS) amplifier, and it may be seen that the nonlinear characteristic is output together therewith.

iₒᵤₜ=gₘVgs+g′ₘV_{gs}²+g″ₘV_{gs}³ Equation 2:

Referring to Equation 2, iₒᵤₜ represents the output current of the NMOS amplifier, and V_{gs} represents the gate-source voltage of the NMOS amplifier.

As described above, the RF signal input to the low-noise amplifier 100 is amplified by the transistor M1, and the RF signal amplified by the transistor M1 is input to the source of the transistor M3. In an example, when the input RF signal passes through the transistor M1 and the transistor M3 connected to each other with a cascode structure, the output current (i_{M1-M3}) may be expressed as Equation 3 below by the cascode current equation.

i_{M1-M3}=gₘ₁gₘ₃Vᵢₙ+g′ₘ₁g′ₘ₃Vᵢₙ²+g″ₘ₁g″ₘ₃Vᵢₙ³ Equation 3:

Referring to Equation 3, Vin represents the RF signal input to the low-noise amplifier 100, that is, the RF signal input to the gate of the transistor M1. gₘ₁ denotes the transconductance of the transistor M1, and gₘ₃ denotes the transconductance of the transistor M3.

In an example, the RF signal amplified by the transistor M1 may also be input to the gate of transistor M2. That is, when the input RF signal passes through the transistors M1 and M2 that are connected to each other with a cascade structure, the output current (i_{M1-M2}) may be indicated as Equation 4 below by the cascade current equation.

$${i}_{M 1 - M 2} = - {g}_{m 2} ( \frac{{g}_{m 1}}{{g}_{m 3}} ) + {{g}_{m 2}^{′} ( \frac{{g}_{m 1}^{′}}{{g}_{m 3}^{′}} )}^{2} - {{g}_{m 2}^{″} ( \frac{{g}_{m 1}^{″}}{{g}_{m 3}^{″}} )}^{3} \qquad Equation 4$$

Assuming that the drain impedance (R_{D,M1}) of the transistor M1 is similar to the input impedance (R_{in,M3}) of the transistor M3, the relationship of Equation 5 below may be established.

R_{D,M1}=R_{in,M3}=1/gₘ₃ Equation 5:

In an example, considering Equation 5, the RF output voltage of the transistor M1 may be expressed as Equation 6 below.

$$\frac{{V}_{out , M 1}}{{V}_{in , M 1}} = - {g}_{m 1} {R}_{D , M 1} = - \frac{{g}_{m 1}}{{g}_{m 3}} \qquad Equation 6$$

Since the RF output voltage of the transistor M1 may be input to the gate of the transistor M2, when applying Equation 6 to Equation 2, the output current (i_{M1-M2}) may be expressed as Equation 4.

Additionally, since the drain of the transistor M2 and the drain of the transistor M3 are connected to each other by the node N1, the final output current iₒᵤₜ may be expressed as the sum of Equation 3 and Equation 4. That is, the final output current iₒᵤₜ may be expressed as Equation 7 below.

$${i}_{out} = {i}_{M 1 - M 3} + {i}_{M 1 - M 2} = ( {g}_{m 1} {g}_{m 3} {v}_{in} - {g}_{m 2} ( \frac{{g}_{m 1}}{{g}_{m 3}} ) ) + ( {g}_{m 1}^{′} {g}_{m 3}^{′} {v}_{in}^{2} + {{g}_{m 2}^{′} ( \frac{{g}_{m 1}^{′}}{{g}_{m 3}^{′}} )}^{2} ) + ( {g}_{m 1}^{″} {g}_{m 3}^{″} {v}_{in}^{3} - {{g}_{m 2}^{″} ( \frac{{g}_{m 1}^{″}}{{g}_{m 3}^{″}} )}^{3} ) \qquad Equation 7$$

Referring to Equation 7, the RF signal input to the transistor M2 and the transistor M3 may be amplified into a signal having opposite phases. In an example, since the drain of the transistor M2 and the drain of the transistor M3 may be connected by the node N1, third order intermodulation (IMD) is offset and becomes small. In an example, it may be necessary to adjust the sizes and bias points of the transistors M1, M2, and M3 to minimize the attenuation of a fundamental signal and to maximize the attenuation of the third order IMD component.

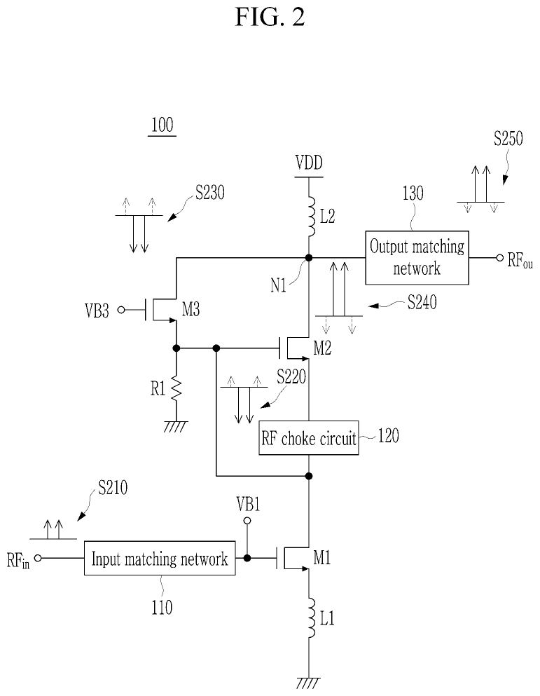

FIG. 2 illustrates a view of a phase relationship of an RF signal in the example low-noise amplifier of FIG. 1.

Referring to FIG. 2, the solid line represents the fundamental signal, and the dotted line represents the signal of the third order IMD component.

Signal S210 represents the input RF signal input to the low-noise amplifier 100. The RF signal such as S210 may be amplified by the transistor M1, and the amplified signal such as signal S220 is output from the drain of the transistor M1. Referring to signal S220, the phase of the fundamental signal is inverted, and the signal of the third order IMD component may be generated due to the nonlinear characteristic of the transistor M1.

The output RF signal S220 of the transistor M1 is input to the source of the transistor M3 and the gate of transistor M2. The transistor M1 and the transistor M3 are connected to each other in a cascode structure, and the transistor M3 has a common-gate structure. Accordingly, the signal such as S230 is output to the drain of the transistor M3. Referring to signals S220 and S230, the phases of both the fundamental signal and the third order IMD component are not inverted.

Then, the output RF signal S220 of the transistor M1 is input to the gate of the transistor M2. The transistor M1 and the transistor M2 are connected to each other in a cascade structure, and the transistor M2 has a common-source structure. Accordingly, the signal such as signal S240 is output from the drain of the transistor M2. Referring to signal S220 and signal S240, the phases of both the fundamental signal and the signal of the third order IMD component are inverted.

The signal such as signal S230 and the signal such as signal S240 are added to each other by or at the node N1, thereby generating the final output signal such as signal S250. Referring to signal S230 and signal S240, since the phases of the signals of the third order IMD components are opposite to each other, the signals of the third order IMD components are offset to each other in the final output signal RFₒᵤₜ. Accordingly, in the final RF output signal of the low-noise amplifier 100 according to an example, the third order IMD component is attenuated, so that the nonlinear characteristic may be improved.

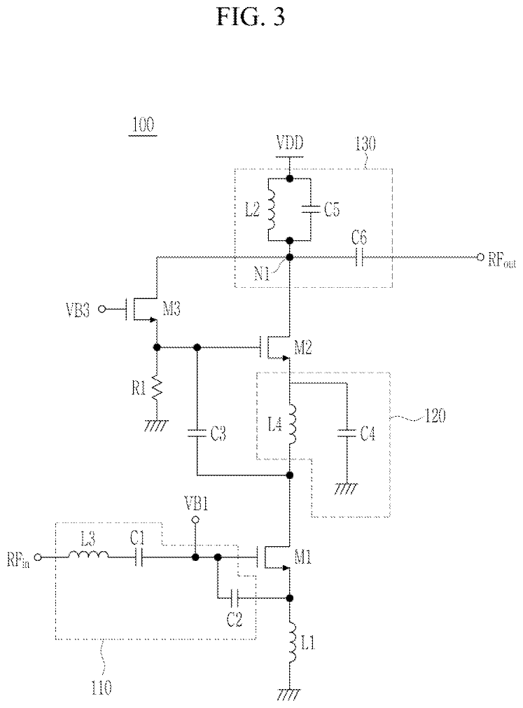

FIG. 3 is a circuit illustrating a detailed configuration of the example low-noise amplifier of FIG. 1. Specifically, FIG. 3 illustrates an example of the input matching network 110, the RF choke circuit 120, and the output matching network 130 among the configurations of FIG. 1.

Referring to FIG. 3, the input matching network 110 may include an inductor L3, a capacitor C1, and a capacitor C2. A first terminal of the inductor L3 may be connected to the RF input terminal RFin, and the capacitor C1 may be connected to a second terminal of the inductor L3 and the gate of the transistor M1. The capacitor C2 may be connected between the gate and the source of the transistor M1. In an example, the capacitor C1 may be implemented as a coupling capacitor, and the capacitor C2 may supplement a gate-source parasitic capacitance of the transistor M1. On the other hand, the input matching network 110 composed of the inductor L3, the capacitor C1, and the capacitor C2, and the inductor L1, may achieve simultaneously input and noise impedance matching (SINM).

In an example, the capacitor C3 may be connected between the drain of the transistor M1 and the gate of the transistor M2. The capacitor C3 may be implemented as a coupling capacitor, through which the amplified output RF signal of the transistor M1 may be transmitted to the gate of transistor M2 and the source of the transistor M3.

The RF choke circuit 120 may include an inductor L4 and a capacitor C4. The inductor L4 may be connected between the drain of the transistor M1 and the source of the transistor M2. The capacitor C4 may be connected between the source of the transistor M2 and the ground. The inductor L4 may prevent the amplified output RF signal of the transistor M1 (the RF signal output from the drain of the transistor M1) from flowing into the source of the transistor M2. Additionally, the capacitor C4 may bypass the RF signal that may pass through the inductor L4 to the ground.

The output matching network 130 may include the capacitor C5, the capacitor C6, and the inductor L2 described in FIG. 1. The capacitor C5 may be coupled to both terminals of the inductor L2 in parallel, and the capacitor C5 and the inductor L2 may form an LC parallel circuit. The capacitor C6 may be connected between the node N1 and the RF output terminal RFₒᵤₜ, and may be implemented as an output impedance matching and a coupling capacitor. Additionally, the inductor L2 may perform an RF choke role and an output impedance matching role. The values of the inductor L2, the capacitor C5, and the capacitor C6 may be set to values that simultaneously satisfy the desired gains and the output impedance characteristic in the operating frequency band.

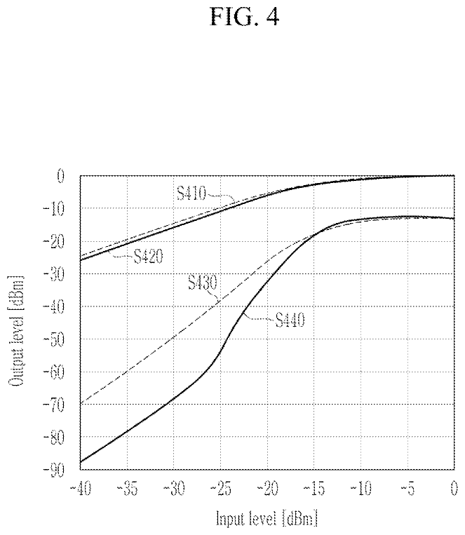

FIG. 4 is a graph illustrating a simulation result for an example low-noise amplifier 100 according to an embodiment.

Referring to FIG. 4, S410 indicates P1 dB for the low-noise amplifier without the transistor M3, and S420 indicates P1 dB for the low-noise amplifier 100 with the transistor M3. Further, S430 denotes a third order IMD (i.e., IIP3) for the low-noise amplifier without the transistor M3, and S440 denotes a third order IMD for the low-noise amplifier 100 with the transistor M3.

Referring to S430 and S440, in the low-noise amplifier 100 according to an embodiment, the third order IMD component is attenuated, and it may be confirmed that the nonlinear characteristic is improved.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A low-noise amplifier, comprising:
a first transistor configured to amplify an input signal;
a second transistor configured to amplify an output signal of the first transistor; and
a third transistor configured to amplify the output signal of the first transistor,
wherein a first signal comprising a sum of an output signal of the second transistor and an output signal of the third transistor is output to an output terminal.

2. The low-noise amplifier of claim 1, wherein the second transistor forms a cascade structure with the first transistor.

3. The low-noise amplifier of claim 1, wherein the third transistor forms a cascode structure with the first transistor.

4. The low-noise amplifier of claim 1, wherein:
a drain of the second transistor and a drain of the third transistor are connected to each other at a node, and
the first signal is output from the node.

5. The low-noise amplifier of claim 4, wherein:
the second transistor is configured to have a common-source structure, and the third transistor is configured to have a common-gate structure.

6. The low-noise amplifier of claim 5, wherein:
the first transistor is configured to have a common-source structure.

7. The low-noise amplifier of claim 4, wherein:
the output signal of the first transistor is input to a control terminal of the second transistor, and
the output signal of the first transistor is input to a source of the third transistor.

8. The low-noise amplifier of claim 1, further comprising:
an input matching network connected to an input terminal to which an input signal is input, and a control terminal of the first transistor, and
the input matching network comprises:
an inductor which has a first terminal connected to the input terminal;
a first capacitor connected between a second terminal of the inductor and the control terminal of the first transistor; and
a second capacitor connected between the control terminal of the first transistor and a source of the first transistor.

9. The low-noise amplifier of claim 4, further comprising:
an RF (Radio Frequency) choke circuit connected between a drain of the first transistor from which the output signal of the first transistor is output, and a source of the second transistor.

10. The low-noise amplifier of claim 9, wherein:
the RF choke circuit comprises:
an inductor connected between the drain of the first transistor and the source of the second transistor; and
a capacitor connected between the source of the second transistor and a ground.

11. The low-noise amplifier of claim 1, wherein:
a phase for a nonlinear component comprised in the output signal of the second transistor and a phase for a nonlinear component comprised in the output signal of the third transistor are opposite to each other.

12. A method, comprising:
amplifying a received Radio Frequency (RF) signal by a first transistor and generating a first amplified signal;
amplifying the first amplified signal with a second transistor to generate a second amplified signal;
amplifying the first amplified signal with a third transistor to generate a third amplified signal; and
combining the second amplified signal and the third amplified signal, and outputting the combined signal to an output terminal.

13. The method of claim 12, wherein the second transistor is connected to the first transistor with a cascade structure.

14. The method of claim 12, wherein the third transistor is connected to the first transistor with a cascode structure.

15. The method of claim 12, wherein:
the second amplified signal and the third amplified signal are combined at a node where a drain of the second transistor and a drain of the third transistor are connected.

16. The method of claim 12, wherein:
a phase for a nonlinear component comprised in the second amplified signal and a phase for a nonlinear component comprised in the third amplified signal are opposite to each other.

17. The method of claim 15, wherein:
the generating of the second amplified signal comprises:
inputting the first amplified signal to a control terminal of the second transistor; and
amplifying the first amplified signal to generate the second amplified signal, and outputting the generated second amplified signal to the drain of the second transistor.

18. The method of claim 17, wherein:
the generating of the third amplified signal comprises:
inputting the first amplified signal to a source of the third transistor; and
amplifying the first amplified signal to generate the third amplified signal, and outputting the generated third amplified signal to the drain of the third transistor.
